(19) United States
(12) Patent Application Publication
(10) Pub. No.: US 2025/0180603 A1
(43) Pub. Date: Jun. 5, 2025

(54) ELECTRO-CONDUCTIVE CONTACT PIN AND VERTICAL PROBE CARD HAVING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Chang Hee HONG, Gyeonggi-do (KR)

(73) Assignee: POINT ENGINEERING CO., LTD., Chungcheongnam-do (KR)

(21) Appl. No.: 18/685,918

(22) PCT Filed: Aug. 3, 2022
(86) PCT No.: PCT/KR2022/011456

§ 371 Date: Feb. 23, 2024

(30) Foreign Application Priority Data
Aug. 30, 2021 (KR) 10-2021-0114421

(51) Int. Cl. G01R 1/067; G01R 1/073; H01L 21/66

(52) U.S. Cl. CPC G01R 1/06716; G01R 1/07314; H01L 22/34

(57) ABSTRACT

Proposed are an electro-conductive contact pin capable of effectively testing the electrical characteristics of a test object without a body thereof being elastically bent or curved in a convex shape in the horizontal direction by pressure applied to opposite ends thereof, and a vertical probe card having the same.

### TECHNICAL FIELD

The present disclosure relates to an electro-conductive contact pin and a vertical probe card having the same.

### BACKGROUND ART

FIG. 1 is a view schematically illustrating a vertical probe card 1 according to the related art, and FIGS. 2 and 3 are enlarged views illustrating a probe head 4 illustrated in FIG. 1.

The vertical probe card 1 generally includes a circuit board 2, a space transformer 3 provided under the circuit board 2, and the probe head 4 provided under the space transformer 3.

The probe head 4 includes a plurality of probe pins 7 and guide plates 5 and 6 having guide holes into which the probe pins 7 are inserted. The probe head 4 includes an upper guide plate 5 and a lower guide plate 6. The upper guide plate 5 and the lower guide plate 6 are fixedly installed through a spacer. The probe pins 7 have a structure elastically deformable between the upper guide plate 5 and the lower guide plate 6, and these probe pins 7 are adopted to constitute the vertical probe card 1.

Referring to FIGS. 2 and 3, a test for electrical characteristics of a semiconductor device is performed by approaching a wafer W to the probe card 1 having the plurality of probe pins 7 and then bringing the respective probe pins 7 into contact with corresponding electrode pads WP on the wafer W. After the probe pins 7 reach positions where the probe pins 7 are brought into contact with the electrode pads WP, an overdrive process is performed to further lift the wafer W by a predetermined height toward the probe card 1. The overdrive process is inevitable because there is a difference in length between the plurality of probe pins 7 due to errors in a manufacturing process, and there is a slight difference in flatness between the guide plates 5 and 6 and the space transformer 3, and there is a difference in height between the electrode pads WP.

During the overdrive process, an oxide layer 8 formed on each electrode pad WP is removed and each probe pin 7 and a conductive material layer of the electrode pad WP are electrically connected to each other, whereby the electrical characteristics of the semiconductor device are tested.

In order to ensure good electrical and mechanical contact for all the probe pins 7, an overdrive with sufficient upward stroke is required. Consequently, a greater pressing force than a certain level is required to provide a sufficient overdrive for the plurality of probe pins 7. However, this high pressing force causes the probe pins 7 to apply excessive pressure to inner walls of the guide holes of the guide plates 5 and 6. Such excessive pressure results in abrasion of the inner walls of the guide holes, generating foreign substances. These foreign substances fall to the electrode pads WP, thereby making it difficult to test electrical characteristics. In addition, since the overdrive process is repeated with excessive pressure, fatigue failure of the probe pins 7 occurs in a short period of time.

Meanwhile, the probe pins 7 used in the related-art vertical probe card 1 are inserted into the upper and lower guide plates 5 and 6 and are buckled in one direction by the pressure applied to opposite ends thereof while being supported by the guide plates 5 and 6. With the recent trend in semiconductor devices toward the integration of multiple functions in one device and faster processing speed, the number of input/output terminals has been increased and the pitch between electrode pads of the semiconductor device has been decreased. In order to cope with the trend toward a narrower pitch, the probe pins 7 have to also be arranged at a narrower pitch. However, when the probe pins 7 arranged at a narrower pitch are buckled, a problem occurs in that adjacent probe pins 7 are brought into contact with each other and thus are short-circuited. In addition, in order to arrange the probe pins 7 at a narrower pitch, the guide holes have to also be arranged at a narrower pitch. As a result, the clearance width between adjacent guide holes is reduced, making it more difficult to process the guide holes. This also reduces the rigidity of the guide plates 5 and 6. In particular, the probe pins 7 continuously apply pressure to the guide plates 5 and 6 as they are buckled, so the fatigue failure rate of the guide plates 5 and 6 is increased.

Until now, as the probe pins 7 used in the vertical probe card 1, there has been used only (i) a structure pre-deformed at the time of manufacture (this type of probe pin 7 is called a “cobra pin” in the field) or (ii) a structure in which a probe pin 7 is straight at the time of manufacture and then is deformed by moving a guide plate in a horizontal direction (this type of probe pin 7 is called a “straight pin” in the field).

However, the above series of problems are caused by the use of the cobra pin or the straight pin for the vertical probe card 1. In other words, the above problems occur because of the structure in which a body of each probe pin 7 is elastically bent or curved in a convex shape in the horizontal direction by the pressure applied to the opposite ends thereof.

### DOCUMENTS OF RELATED ART

(Patent Document 1) Korean Patent No. 10-1913355

### DISCLOSURE OF INVENTION

### Technical Problem

Accordingly, the present disclosure has been made keeping in mind the above problems occurring in the related art, and ab objective of the present disclosure is to provide an electro-conductive contact pin capable of effectively testing the electrical characteristics of a test object without a body thereof being elastically bent or curved in a convex shape in the horizontal direction by pressure applied to opposite ends thereof, and to provide a vertical probe card having the same.

### Solution to Problem

In order to achieve the above objective, according to one aspect of the present disclosure, there is provided an electro-conductive contact pin including: a first plunger positioned at a first end side of the electro-conductive contact pin and having an end serving as a first contact point; a second plunger positioned at a second side of the electro-conductive contact pin and having an end serving as a second contact point; and an elastic portion having a repetitive bending pattern and configured to elastically displace the first plunger and the second plunger in a length direction of the electro-conductive contact pin, wherein the second plunger may include a first metal portion and a second metal portion, and the second metal portion may be in contact with a side surface of the first metal portion.

Furthermore, the first metal portion may be provided by stacking a plurality of metal layers, and the second metal portion may be provided by a single metal layer.

Furthermore, the first metal portion may be provided by stacking at least three metal layers, and the second metal portion may be in contact with the first metal portion at at least one interface.

Furthermore, the first metal portion may surround three side surfaces of the second metal portion, and a side surface of the second metal portion not surrounded by the first metal portion may serve as the second contact point.

Furthermore, the first metal portion, the second metal portion, and the first metal portion may be positioned sequentially in a widthwise cross-section of the second plunger.

Furthermore, the second metal portion may be composed of a single metal layer, and the single metal layer constituting the second metal portion may be made of a material different from that of a metal layer constituting the first metal portion.

Furthermore, the first plunger and the clastic portion may be provided by stacking a plurality of metal layers the same as a metal layer constituting the first metal portion, and the second metal portion may be provided by a single metal layer.

Furthermore, a support portion configured to guide the elastic portion to be compressed and extended in the length direction of the electro-conductive contact pin and configured to prevent the elastic portion from being buckled when compressed may be provided outside the clastic portion along the length direction of the electro-conductive contact pin.

Furthermore, an actual width of a plate constituting the support portion may be equal to an actual width of a plate constituting the elastic portion.

Furthermore, the first plunger, the second plunger, the clastic portion, and the support portion may be integrally connected to each other to form a single body.

Furthermore, the elastic portion may have a uniform cross-sectional shape in a thickness direction of the electro-conductive contact pin, and the elastic portion may have a uniform thickness throughout.

Furthermore, a fine trench may be provided in a side surface of each of the first plunger, the second plunger, and the elastic portion.

Furthermore, the clastic portion may include: a first elastic portion connected to the first plunger; a second elastic portion connected to the second plunger; and an intermediate fixing portion connected to the first elastic portion and the second elastic portion between the first elastic portion and the second elastic portion and provided integrally with the support portion.

According to another aspect of the present disclosure, there is provided a vertical probe card that is used in a test process of testing a chip manufactured on a wafer during a semiconductor manufacturing process and is capable of coping with a narrower pitch, the vertical probe card including: a space transformer having a connection pad; a guide plate provided under the space transformer so as to be spaced apart from the space transformer; and an electro-conductive contact pin inserted and installed into a hole of the guide plate, wherein the electro-conductive contact pin may include: a first plunger positioned at a first end side of the electro-conductive contact pin and having an end serving as a first contact point; a second plunger positioned at a second side of the electro-conductive contact pin and having an end serving as a second contact point; and an elastic portion having a repetitive bending pattern and configured to elastically displace the first plunger and the second plunger in a length direction of the electro-conductive contact pin, wherein the second plunger may include a first metal portion and a second metal portion, and the second metal portion may be in contact with a side surface of the first metal portion.

Furthermore, a support portion configured to guide the elastic portion to be compressed and extended in the length direction of the electro-conductive contact pin and configured to prevent the elastic portion from being buckled when compressed may be provided outside the clastic portion along the length direction of the electro-conductive contact pin, and a locking portion configured to allow the support portion to be caught and fixed to the guide plate may be provided on an outer wall of the support portion.

### Advantageous Effects of Invention

The present disclosure can provide an electro-conductive contact pin capable of effectively testing the electrical characteristics of a test object without a body thereof being elastically bent or curved in a convex shape in the horizontal direction by pressure applied to opposite ends thereof, and provide a vertical probe card having the same.

### BRIEF DESCRIPTION OF DRAWINGS

FIG. 1 is a view schematically illustrating a vertical probe card according to the related art.

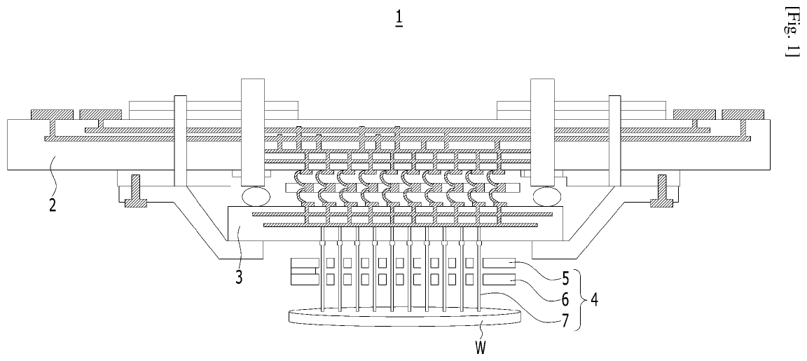

FIGS. 2 and 3 are enlarged views illustrating a probe head illustrated in FIG. 1.

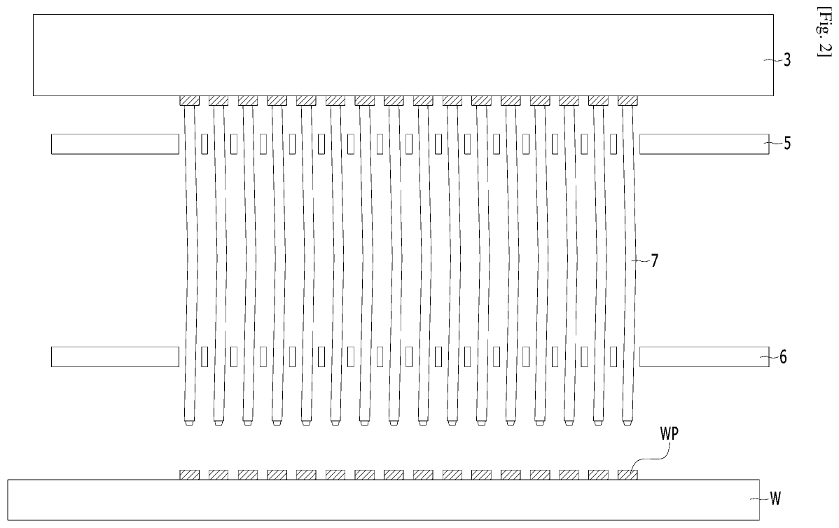

FIG. 4 is a view illustrating a state in which a plurality of electro-conductive contact pins according to a first exemplary embodiment of the present disclosure are installed in an upper guide plate and a lower guide plate.

FIG. 5a is a plan view illustrating an electro-conductive contact pin according to the first exemplary embodiment of the present disclosure.

FIG. 5b is a perspective view illustrating the electro-conductive contact pin according to the first exemplary embodiment of the present disclosure.

FIG. 6a is an enlarged plan view of part A illustrated in FIG. 5a.

FIG. 6b is an enlarged perspective view of part A illustrated in FIG. 5a.

FIG. 7a is an enlarged plan view of part B illustrated in FIG. 5a.

FIG. 7b is an enlarged perspective view of part B illustrated in FIG. 5a.

FIG. 8a is an enlarged plan view of part C illustrated in FIG. 5a.

FIG. 8b is an enlarged perspective view of part C illustrated in FIG. 5a.

FIGS. 9a to 9f are views illustrating a method of manufacturing the electro-conductive contact pin according to the first exemplary embodiment of the present disclosure.

FIG. 10 is an actual image of the electro-conductive contact pin according to the first exemplary embodiment of the present disclosure.

FIG. 11 is a view illustrating a side surface of the electro-conductive contact pin according to the first exemplary embodiment of the present disclosure.

FIGS. 12 and 13 are views illustrating a comparison between a vertical probe card according to an exemplary embodiment of the present disclosure and the vertical probe card according to the related art.

FIG. 14a is a plan view illustrating an electro-conductive contact pin according to a second exemplary embodiment of the present disclosure.

FIG. 14b is a perspective view illustrating the electro-conductive contact pin according to the second exemplary embodiment of the present disclosure.

FIG. 15a is an enlarged plan view of part A illustrated in FIG. 14a.

FIG. 15b is an enlarged perspective view of part A illustrated in FIG. 14a.

FIG. 16a is an enlarged plan view of part B illustrated in FIG. 14a.

FIG. 16b is an enlarged perspective view of part B illustrated in FIG. 14a.

FIG. 17a is an enlarged plan view of part C illustrated in FIG. 14a.

FIG. 17b is an enlarged perspective view of part C illustrated in FIG. 14a.

### MODE FOR THE INVENTION

Contents of the description below merely exemplify the principle of the disclosure. Therefore, those of ordinary skill in the art may implement the theory of the disclosure and invent various apparatuses which are included within the concept and the scope of the disclosure even though it is not clearly explained or illustrated in the description. Furthermore, in principle, all the conditional terms and embodiments listed in this description are clearly intended for the purpose of understanding the concept of the disclosure, and one should understand that this disclosure is not limited to the exemplary embodiments and the conditions.

The above described objectives, features, and advantages will be more apparent through the following detailed description related to the accompanying drawings, and thus those of ordinary skill in the art may easily implement the technical spirit of the disclosure.

The embodiments of the present disclosure will be described with reference to cross-sectional views and/or perspective views which schematically illustrate ideal embodiments of the present disclosure. For explicit and convenient description of the technical content, sizes or thicknesses of films and regions in the figures may be exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise”, “include”, “have”, etc. when used herein, specify the presence of stated features, integers, steps, operations, elements, components, and/or combinations thereof but do not preclude the presence or addition of one or more other features, integers, steps, operations, elements, components, and/or combinations thereof.

Reference will now be made in greater detail to exemplary embodiments of the present disclosure, examples of which are illustrated in the accompanying drawings. Wherever possible, the same reference numerals will be used throughout different embodiments and the description to refer to the same or like elements or parts. In addition, the configuration and operation already described in other embodiments will be omitted for convenience.

An electro-conductive contact pin 100, 200 according to each exemplary embodiment of the present disclosure described below is provided in a test apparatus and is used to transmit electrical signals by making electrical and physical contact with a test object. The test apparatus may be a test apparatus used in a semiconductor manufacturing process, for example, a probe card or a test socket. The electro-conductive contact pin 100, 200 may be a probe pin provided in a probe card to test a semiconductor chip, or a socket pin provided in a test socket for testing a semiconductor package to test the semiconductor package.

The electro-conductive contact pin 100, 200 according to each exemplary embodiment of the present disclosure may be employed in a vertical probe card. A vertical probe card according to an exemplary embodiment of the present disclosure is used in a test process of testing chips manufactured on a wafer during a semiconductor manufacturing process, and is capable of coping with a narrower pitch.

The vertical probe card according to the exemplary embodiment of the present disclosure includes a space transformer ST having a connection pad CP; guide plates GP1 and GP2 provided under the space transformer ST so as to be spaced apart from the space transformer ST; and the electro-conductive contact pin 100, 200 inserted and installed into a hole of each of the guide plates GP1 and GP2.

Hereinafter, a first embodiment according to the present disclosure will be described with reference to the drawings.

In the following description, the width direction of an electro-conductive contact pin refers to the ±x direction indicated in the drawings, the length direction of the electro-conductive contact pin refers to the ty direction indicated in the drawings, and the thickness direction of the electro-conductive contact pin refers to the ±z direction indicated in the drawings. The electro-conductive contact pin has an overall length L in the length direction (±y direction), an overall thickness H in the thickness direction (±2 direction) orthogonal to the length direction, and an overall width W in the width direction (±x direction) orthogonal to the length direction.

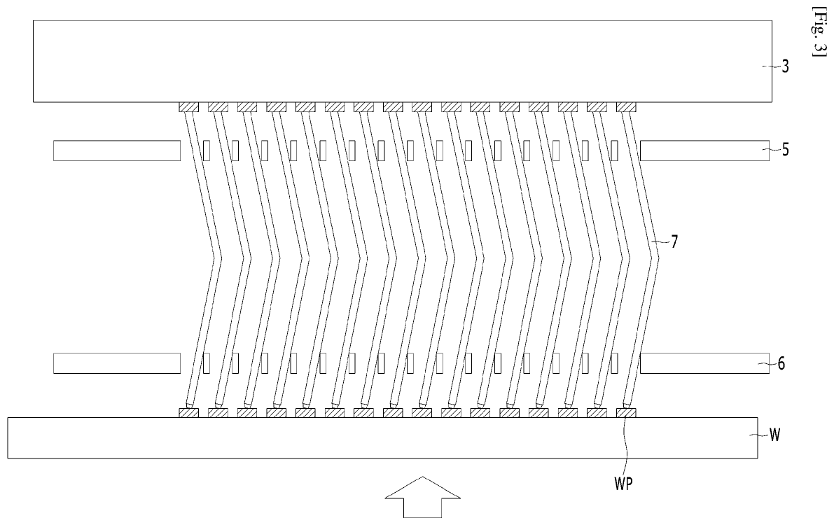

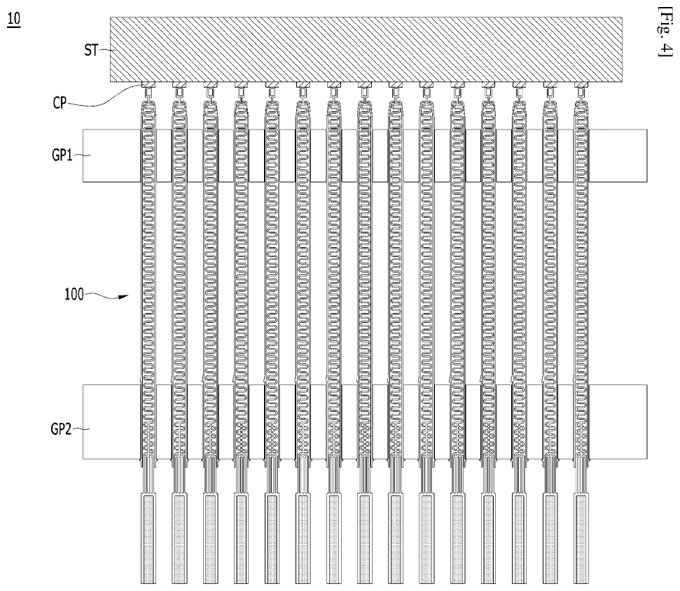

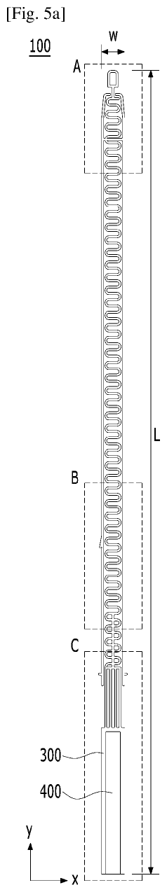

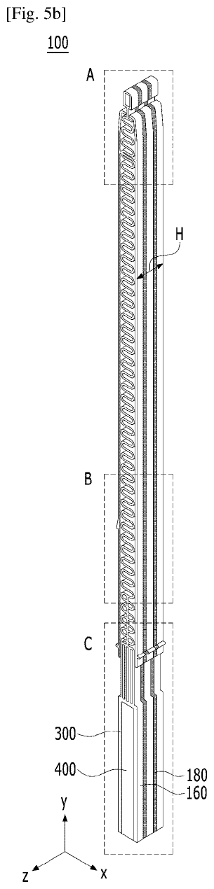

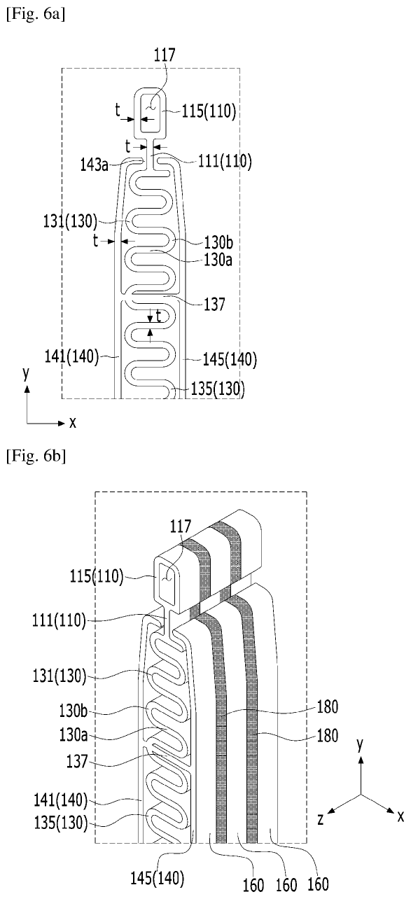

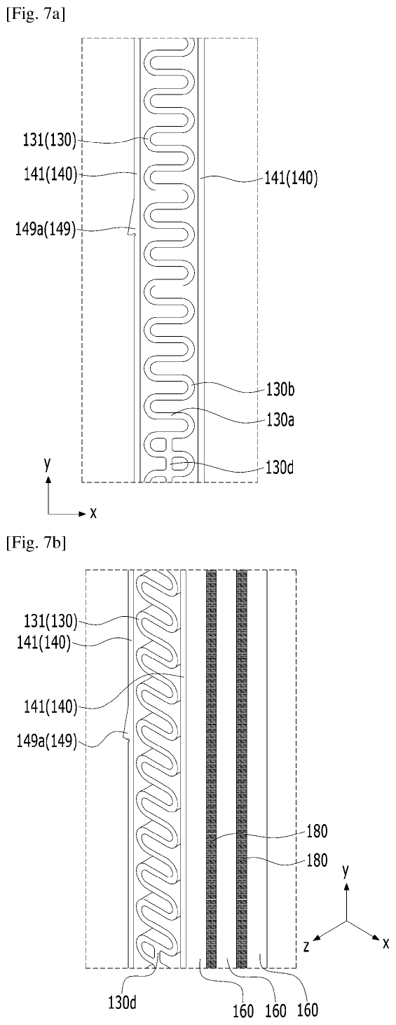

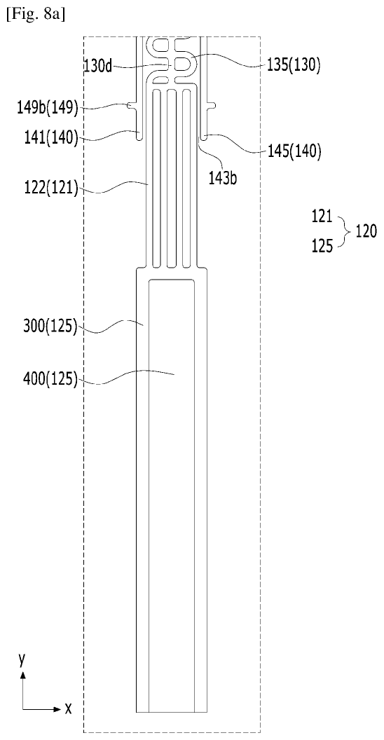

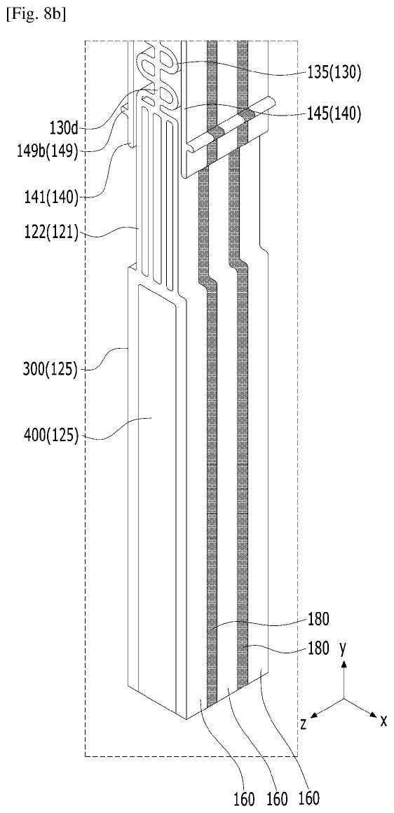

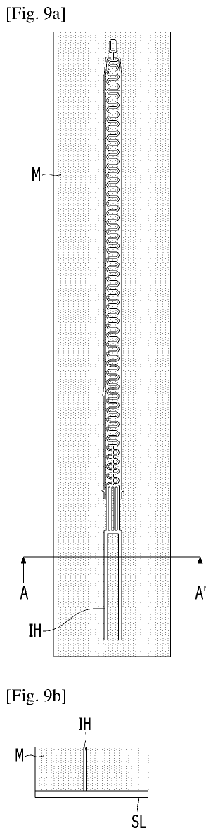

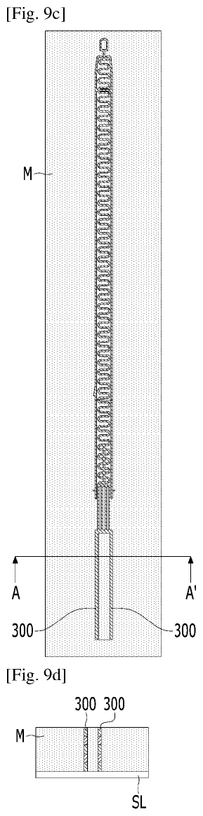

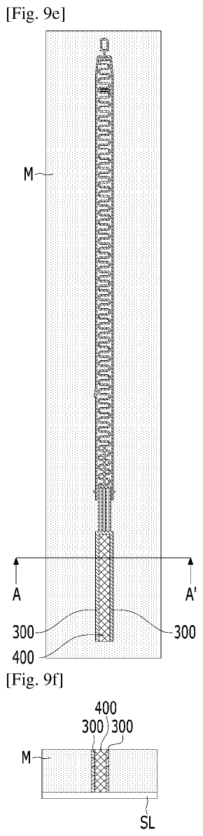

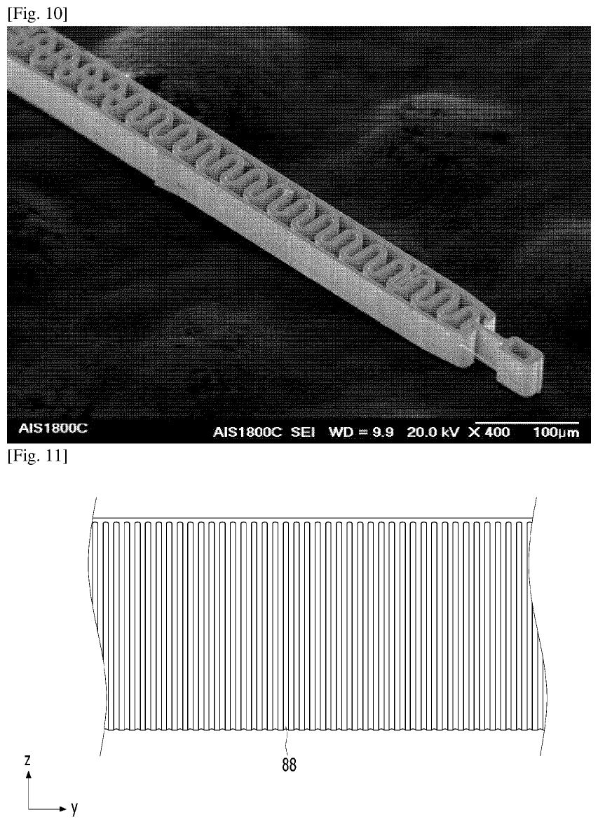

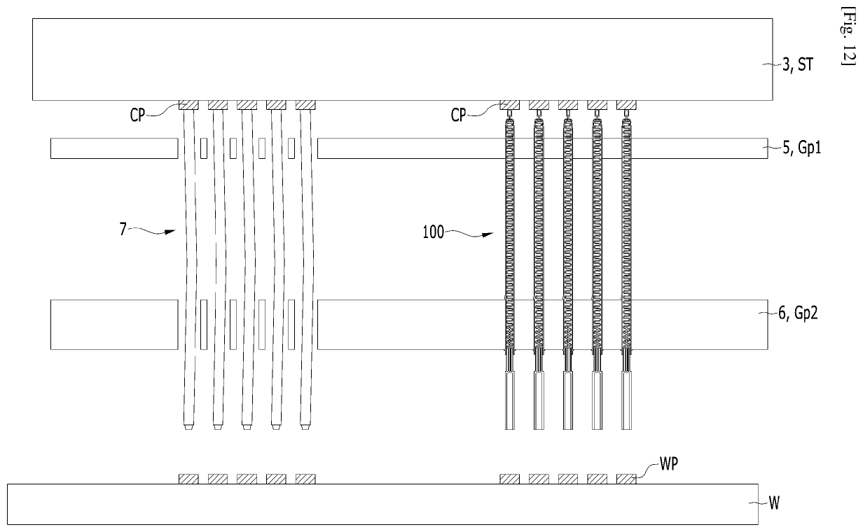

FIG. 4 is a view illustrating a state in which a plurality of electro-conductive contact pins 100 according to a first exemplary embodiment of the present disclosure are installed in an upper guide plate and a lower guide plate. FIG. 5a is a plan view illustrating an electro-conductive contact pin 100 according to the first exemplary embodiment of the present disclosure. FIG. 5b is a perspective view illustrating the electro-conductive contact pin 100 according to the first exemplary embodiment of the present disclosure. FIG. 6a is an enlarged plan view of part A illustrated in FIG. 5a. FIG. 6b is an enlarged perspective view of part A illustrated in FIG. 5a. FIG. 7a is an enlarged plan view of part B illustrated in FIG. 5a. FIG. 7b is an enlarged perspective view of part B illustrated in FIG. 5a. FIG. 8a is an enlarged plan view of part C illustrated in FIG. 5a. FIG. 8b is an enlarged perspective view of part C illustrated in FIG. 5a. FIGS. 9a to 9f are views illustrating a method of manufacturing the electro-conductive contact pin 100 according to the first exemplary embodiment of the present disclosure. FIG. 10 is an actual image of the electro-conductive contact pin 100 according to the first exemplary embodiment of the present disclosure. FIG. 11 is a view illustrating a side surface of the electro-conductive contact pin 100 according to the first exemplary embodiment of the present disclosure. FIGS. 12 and 13 are views illustrating a comparison between a vertical probe card according to an exemplary embodiment of the present disclosure and a vertical probe card according to the related art.

The vertical probe card 10 according to the exemplary embodiment of the present disclosure is used in a test process of testing chips manufactured on a wafer during a semiconductor manufacturing process, and is capable of coping with a narrower pitch. The vertical probe card 10 according to the exemplary embodiment of the present disclosure is more useful for testing non-memory semiconductor chips such as microprocessors, microcontrollers, and ASICs.

The vertical probe card 10 according to the exemplary embodiment of the present disclosure includes a space transformer ST having a connection pad CP; the guide plates GP1 and GP2 provided under the space transformer ST so as to be spaced apart from the space transformer ST; and the electro-conductive contact pin 100 inserted and installed into a hole of each of the guide plates GP1 and GP2.

The electro-conductive contact pin 100 includes: a first plunger 110 positioned at an upper portion thereof and connected to the connection pad CP of the space transformer ST; a second plunger 120 positioned at a lower portion thereof and connected to a chip; and an elastic portion 130 elastically displacing the first plunger 110 and the second plunger 120 in the length direction of the electro-conductive contact pin 100. The elastic portion 130 has a uniform cross-sectional shape in the thickness direction of the electro-conductive contact pin 100, and the elastic portion 130 has a uniform thickness in the width direction and the length direction of the electro-conductive contact pin 100.

In addition, the electro-conductive contact pin 100 includes a support portion 140 provided outside the elastic portion 130 along the length direction of the electro-conductive contact pin 100 so as to guide the elastic portion 130 to be compressed and extended in the length direction of the electro-conductive contact pin 100 and prevent the elastic portion 130 from being buckled when compressed.

The pitch between the electro-conductive contact pins 100 installed in the guide plates GP1 and GP2 of the vertical probe card 10 is in the range of 50 μm to 150 μm. The lateral width of the electro-conductive contact pin 100 is in the range of 40 μm to 200 μm, and the thickness of the electro-conductive contact pin 100 is in the range of 40 μm to 200 μm.

The elastic portion 130 includes: a first elastic portion 131 connected to the first plunger 110; a second elastic portion 135 connected to the second plunger 120; and an intermediate fixing portion 137 connected to the first elastic portion 131 and the second elastic portion 135 between the first elastic portion 131 and the second elastic portion 135 and provided integrally with the support portion 140. The elastic portion 130 has a uniform cross-sectional shape in the thickness direction of the electro-conductive contact pin 100. In addition, the elastic portion 130 has a uniform thickness throughout. Each of the first and second elastic portions 131 and 135 is formed by repeatedly bending a plate having an actual width t in an “S” shape, and the actual width t of the plate is uniform throughout. The ratio of the actual width t of the plate to the thickness of the plate is in the range of 1:5 to 1:30.

Before the electro-conductive contact pin 100 tests a semiconductor chip, the first plunger 110 is in a state in contact with the connection pad CP so that the first elastic portion 130 is compressively deformed in the length direction of the electro-conductive contact pin 100, and the second plunger 120 is in a state not in contact with the chip. Whereas, when the electro-conductive contact pin 100 tests the chip, the second plunger 120 is brought into contact with the chip so that the second elastic portion 135 is compressively deformed.

The first plunger 110 has a first end serving as a free end and a second end connected to the first elastic portion 131 so that the first plunger 110 is elastically movable vertically by contact pressure. The second plunger 120 has a first end serving as a free end and a second end connected to the second elastic portion 135 so that the second plunger 120 is elastically movable vertically by contact pressure.

The first plunger 110 includes a first neck portion 111 and a head portion 115.

The first neck portion 111 has a first end connected to the first elastic portion 131 and a second end connected to the head portion 115. The first neck portion 111 is formed to have a width smaller than that of an upper opening formed between upper ends of the support portion 140 so as to vertically pass through the upper opening.

The actual width t of a plate constituting the first neck portion 111 is configured to be equal to the actual width t of a plate constituting the first elastic portion 131 and/or the support portion 140.

The head portion 115 is connected to an upper portion of the first neck portion 111 and is positioned above the support portion 40. The head portion 115 has a hollow hole 117 therein and has a closed structure. The head portion 115 has a closed quadrangular ring shape and is elastically brought into contact with the connection pad CP.

The actual width t of a plate constituting the head portion 115 is configured to be equal to the actual width t of the plate constituting the first neck portion 111.

The first elastic portion 131 has a first end connected to the first plunger 110 and a second end connected to the intermediate fixing portion 137. The second clastic portion 135 has a first end connected to the second plunger 120 and a second end connected to the intermediate fixing portion 137.

The support portion 140 includes a first support portion 141 provided at a left side of the clastic portion 130 and a second support portion 145 provided at a right side of the clastic portion 130.

The actual width t of the plate constituting each of the first elastic portion 131 and the second elastic portion 135 is configured to be equal to the actual width t of a plate constituting each of the first support portion 141 and the second support portion 145.

A locking portion 149 is provided on an outer wall of the support portion 140 so as to allow the support portion 140 to be caught and fixed to the lower guide plate GP2. The locking portion 149 includes an upper locking portion 149a caught on an upper surface of the lower guide plate GP2 and a lower locking portion 149b caught on a lower surface of the lower guide plate GP2. Of course, alternatively, the locking portion 149 may be provided to allow the support portion 140 to be caught and fixed to the upper guide plate GP1.

The intermediate fixing portion 137 is formed to extend in the width direction of the electro-conductive contact pin 100, and connects the first support portion 141 and the second support portion 145 to each other.

The first clastic portion 131 is provided above the intermediate fixing portion 137, and the second elastic portion 135 is provided below the intermediate fixing portion 137. The first clastic portion 131 and the second elastic portion 135 are compressed or extended with respect to the intermediate fixing portion 137. The intermediate fixing portion 137 is fixed to the first and second support portions 141 and 145 and functions to limit the movement of the first and second elastic portions 131 and 135 when the first and second elastic portions 131 and 135 are compressively deformed.

The intermediate fixing portion 137 separates a region in which the first clastic portion 131 is provided and a region in which the second elastic portion 135 is provided. Therefore, foreign substances introduced into the upper opening 143a are blocked from flowing toward the second elastic portion 135, and foreign substances introduced into a lower opening 143b are also blocked from flowing toward the first clastic portion 131. With this, the movement of the foreign substances introduced into the support portion 140 is limited, thereby preventing the operation of the first and second elastic portions 131 and 135 from being disturbed by the foreign substances.

The first support portion 141 and the second support portion 145 are formed along the length direction of the electro-conductive contact pin 100. The first support portion 141 and the second support portion 145 are integrally connected to the intermediate fixing portion 137 extending along the width direction of the electro-conductive contact pin 100. In addition, the first and second elastic portions 131 and 135 are integrally connected to each other through the intermediate fixing portion 137, so that the electro-conductive contact pin 100 is constructed as a single body.

Each of the first and second clastic portions 131 and 135 is formed by alternately connecting a plurality of straight portions 130a and a plurality of curved portions 130b. Each of the straight portions 130a connects the curved portions 130b adjacent in the left and right directions, and each of the curved portions 130b connects the straight portions 130a adjacent in the upper and lower directions. The curved portions 130b have an arc shape.

The straight portions 130a are disposed at a central portion of each of the first and second clastic portions 131 and 135, and the curved portions 130b are disposed at outer peripheral portions of each of the first and second elastic portions 131 and 135. The straight portions 130a are provided parallel to the width direction so that the curved portions 130b can be more easily deformed by contact pressure.

The first and second elastic portions 131 and 135 are connected to the intermediate fixing portion 137 at the curved portions 130b of the first and second elastic portions 131 and 135. With this, the first and second elastic portions 131 and 135 maintain elasticity with respect to the intermediate fixing portion 137.

While the first clastic portion 131 requires an amount of compression sufficient to allow respective first plungers 110 of the plurality of electro-conductive contact pins 100 to make stable contact with respective connection pads CP of the space transformer ST, the second elastic portion 135 requires an amount of compression sufficient to allow respective second plungers 120 of the plurality of electro-conductive contact pins 100 to make stable contact with respective chips. Therefore, the first elastic portion 131 and the second elastic portion 135 have different spring coefficients from each other. For example, the first elastic portion 131 and the second clastic portion 135 are provided to have different lengths from each other. In addition, the length of the second clastic portion 135 may be configured to be longer than that of the first elastic portion 131.

The clastic portion 130 includes a rigidity retaining portion 130d. The rigidity retaining portion 130d is formed to cross the center of the clastic portion 130 along the length direction of the electro-conductive contact pin 100. The rigidity retaining portion 130d connects the straight portions 130a adjacent in the upper and lower directions so as to prevent the clastic portion 130 from being compressed at the position where the rigidity retaining portion 130d is provided. The rigidity retaining portion 130d is provided on at least a portion of the clastic portion 130 to prevent buckling deformation of the elastic portion 130 inside the support portion 140.

The actual width t of a plate constituting the rigidity retaining portion 130d is configured to be equal to the actual width t of the plate constituting the straight portions 130a and the curved portions 130b.

The rigidity retaining portion 130d may be formed in the second elastic portion 135 having a relatively longer length. More specifically, the rigidity retaining portion 130d is provided at a lower portion of the second elastic portion 135 to prevent buckling of the lower portion of the second elastic portion 135 so that contact pressure is transmitted in the axial direction. With this, a force for compressively deforming the second clastic portion 135 is transmitted in the axial direction, so that the compressive deformation of the second elastic portion 135 can be more easily achieved.

The second plunger 120 includes a second neck portion 121 and a protruding tip 125.

The second neck portion 121 has a first end connected to the second elastic portion 135 and a second end connected to the protruding tip 125. The second neck 121 includes a plurality of beams 122 arranged to be spaced apart from each other. The actual width t of a plate constituting each of the beams 122 is configured to be equal to the actual width t of the plate constituting the second clastic portion 135.

The protruding tip 125 is connected to a lower portion of the second neck portion 121.

The protruding tip 125 includes a first metal portion 300 and a second metal portion 400. The second metal portion 400 is in contact with a side surface of the first metal portion 300.

The first plunger 110, the clastic portion 130, the support portion 140, and the first metal portion 300 are provided by stacking a plurality of metal layers in the thickness direction of the electro-conductive contact pin 100. The plurality of metal layers include a first metal layer 160 and a second metal layer 180. The first metal layer 160 may be made of a metal having relatively high wear resistance compared to the second metal layer 180, preferably a metal selected from rhodium (Rd), platinum (Pt), iridium (Ir), palladium (Pd), nickel (Ni), manganese (Mn), tungsten (W), phosphorus (Ph), or an alloy thereof, or a palladium-cobalt (PdCo) alloy or a palladium-nickel (PdNi) alloy, or a nickel-phosphorus (NiPh) alloy, a nickel-manganese (NiMn) alloy, a nickel-cobalt (NiCo) alloy, or a nickel-tungsten (NiW) alloy. The second metal layer 180 may be made of a metal having relatively high electrical conductivity compared to the first metal layer 160, preferably a metal selected from copper (Cu), silver (Ag), gold (Au), or an alloy thereof.

The first metal layer 160 is disposed on each of the upper and lower sides in the thickness direction of the electro-conductive contact pin 100, and the second metal layer 180 is disposed between the first metal layers 160. For example, the electro-conductive contact pin 100 is provided by sequentially stacking the first metal layer 160, the second metal layer 180, and the first metal layer 160, and the number of stacked layers is at least three.

Unlike the first plunger 110, the elastic portion 130, the support portion 140, and the first metal portion 300, the second metal portion 400 is provided by a single metal layer.

According to the configuration in which an exposed lower end surface of the second metal portion 400 serves as a second contact point, the exposed lower end surface of the second metal portion 400 continuously makes contact with an object and thus is required to have high wear resistance. In this case, the second metal portion 400 may be made of a metal having relatively high wear resistance compared to the first metal layer 160, preferably a metal selected from rhodium (Rd), platinum (Pt), iridium (Ir), palladium (Pd), nickel (Ni), manganese (Mn), tungsten (W), phosphorus (Ph), or an alloy thereof, or a palladium-cobalt (PdCo) alloy or a palladium-nickel (PdNi) alloy, or a nickel-phosphorus (NiPh) alloy, a nickel-manganese (NiMn) alloy, a nickel-cobalt (NiCo) alloy, or a nickel-tungsten (NiW) alloy.

On the other hand, in some cases, according to the configuration in which the exposed lower end surface of the second metal portion 400 serves as the second contact point, the exposed lower end surface of the second metal portion 400 makes contact with the object and thus is required to have high electrical conductivity. In this case, the second metal portion 400 may be made of a metal having relatively high electrical conductivity compared to the second metal layer 160, preferably a metal selected from copper (Cu), silver (Ag), gold (Au), or an alloy thereof.

The single metal layer constituting the second metal portion 400 may be made of a material different from that of the metal layers constituting the first metal portion 300. For example, when the first metal portion 300 is constituted by alternately stacking the first metal layer 160 made of palladium-cobalt (PdCo) and the second metal layer 180 made of copper (Cu), the second metal portion 400 may be made of a single metal of rhodium (Rd). On the other hand, the single metal layer constituting the second metal portion 400 may be made of the same material as any one of the metal layers constituting the first metal portion 300. For example, when the first metal portion 300 is constituted by alternately stacking the first metal layer 160 made of palladium-cobalt (PdCo) and the second metal layer 180 made of copper (Cu), the second metal portion 400 may be made of a single metal of palladium-cobalt (PdCo) or copper (Cu).

The first plunger 110, the clastic portion 130, the support portion 140, and the first metal portion 300 may be simultaneously formed by the same plating process, so that the first plunger 110, the elastic portion 130, and the support portion 140 may be provided by stacking a plurality of metal layers the same as the metal layers constituting the first metal portion 300. In this case, the first plunger 110, the clastic portion 130, the support portion 140, and the first metal portion 300 may be constituted by stacking the same number of metal layers in the same stacking order. Since the second metal portion 400 is formed by a single-layer plating process separate from a multi-layer plating process of forming the first plunger 110, the elastic portion 130, the support portion 140, and the first metal portion 300, the metal layers constituting the first plunger 110, the elastic portion 130, the support portion 140, and the first metal portion 300 are different from the metal layer constituting the second metal portion 400.

The second metal portion 400 is in contact with the first metal portion 300 at at least one interface. The number of the interface between the first metal portion 300 and the second metal portion 400 may be in the range of one to four or more.

Preferably, as illustrated in FIGS. 8a and 8b, the first metal portion 300 surrounds three side surfaces of the second metal portion 400, and a side surface of the second metal portion 400 not surrounded by the first metal portion 300 serves as the second contact point. Since the first metal portion 300 surrounds the three side surfaces of the second metal portion 400, a bonding strength with the second metal portion 400 is improved. In a widthwise cross-section of the protruding tip 125 of the second plunger 120, the first metal portion 300, the second metal portion 400, and the first metal portion 300 are positioned sequentially. In other words, the second metal portion 400 is positioned between the first metal portions 300 in the widthwise cross-section of the protruding tip 125 of the second plunger 120.

At the second contact point, the first metal portion 300 and the second metal portion 400 are exposed together. The width of the second metal portion 400 in the width direction of the protruding tip 125 is configured to be larger than that of the first metal portion 300 positioned at a left side thereof and that of the first metal portion 300 positioned at a right side thereof. With this, the second metal portion 400 rather than the first metal portion 300 is brought into contact with the object.

An upward stroke of the protruding tip 125 may be limited as the protruding tip 125 is brought into contact with lower ends of the support portion 140. The width of the second neck portion 121 is configured to be smaller than that of the gap between the lower ends of the support portion 140 so that the second neck portion 121 is allowed to be moved to the inside of the support portion 140. Meanwhile, the width of the protruding tip 125 is configured to be larger than that of the gap between the lower ends of the support portion 140 so that the protruding tip 125 is limited from being moved to the inside of the support portion 140 when the protruding tip 125 is moved upward.

The plates constituting the first plunger 110, the clastic portion 130, the support portion 140, and the first metal portion 300 may have substantially the same actual width t. With this, it is easy to make the height of each of the metal layers uniform in the multi-layer plating process for forming the metal layers, thereby improving the characteristics of the electro-conductive contact pin 100.

The electro-conductive contact pin 100 according to the exemplary embodiment of the present disclosure is provided as a single body in which thin plates are continuously and integrally connected to each other. The plates constituting the electro-conductive contact pin 100 have a width. Here, the width means a distance between a first surface of the plates and a second surface thereof facing the first surface. The plates constituting the electro-conductive contact pin 100 have a minimum width corresponding to the smallest width and a maximum width corresponding to the largest width. The actual width t of the plates may be an average value of the widths of all the plates, or a median value of the widths of all the plates, or an average value or a median value of the widths of the plates corresponding to at least a part of the configurations constituting the electro-conductive contact pin 100, or an average value or a median value of the width of at least one of the plates corresponding to the elastic portion 130 and the support portion 140, or a value of the width obtained when the plates are continuous with the same width by equal to or larger than 5 μm.

Since the actual width t of the plates is configured to be smaller than the overall thickness H of the plates, a structure in which thin plates stand up in the thickness direction is formed.

The electro-conductive contact pin 100 is provided as a single body, and includes: the support portion 140 formed in the form of a plate extending in the length direction; the intermediate fixing portion 137 provided inside the support portion 140 and formed in the form of a plate extending in the width direction while crossing the support portion 140; the first elastic portion 131 formed in the form of a bent plate above the intermediate fixing portion 137; the second elastic portion 135 formed in the form of a bent plate below the intermediate fixing portion 137; the first plunger 110 formed in the form of a plate at an upper end of the first clastic portion 131; and the second plunger 120 formed in the form of a plate at a lower end of the second clastic portion 135. As described above, the electro-conductive contact pin 100 is provided as a single body in which the plates are integrally connected to each other.

The plates constituting the first and second plungers 110 and 120, the elastic portion 130, and the support portion 140 may be different from each other in the actual width t, but may have the same thickness.

The electro-conductive contact pin 100 according to the exemplary embodiment of the present disclosure is formed such that the actual width t of the plates is small while the overall thickness H of the plates is large. In other words, the overall thickness H is configured to be large compared to the actual width t of the plates. Preferably, the actual width t of the plates constituting the electro-conductive contact pin 100 is in the range of 5 μm to 15 μm, the overall thickness H of the plates is in the range of 40 μm to 200 μm, and the actual width t and the overall thickness H of the plates have a ratio in the range of 1:5 to 1:30. For example, the actual width t of the plates may be substantially 5 μm, and the overall thickness H of the plates may be 50 μm, so that the actual width t and the overall thickness H of the plates may have a ratio of 1:10.

According to the method of manufacturing the electro-conductive contact pin 100 according to the exemplary embodiment of the present disclosure, which will be described later, it is possible to make the actual width t of the plates constituting the clastic portion 130 equal to or less than 10 μm, more preferably 5 μm. Since it becomes possible to form the elastic portion 130 by bending the plates having an actual width t of 5 μm, it is possible to reduce the overall width W of the electro-conductive contact pin 100. As a result, it is possible to cope with a narrower pitch. In addition, since the overall thickness H is configured in the range of 40 μm to 200 μm, it is possible to shorten the length of the elastic portion 130 while preventing damage to the clastic portion 130. Also, it is possible for the elastic portion 130 to have an appropriate contact pressure by the configuration of the plates even when the length thereof is shortened. Furthermore, as it becomes possible to increase the overall thickness H compared to the actual width t of the plates constituting the elastic portion 130, the resistance to moments acting in the front and rear directions of the elastic portion 130 is increased, resulting in improved contact stability.

As it becomes possible to shorten the length of the elastic portion 130, the overall thickness H and the overall length L of the electro-conductive contact pin 100 have a ratio in the range of 1:3 to 1:9. Preferably, the overall length L of the electro-conductive contact pin 100 is in the range of 300 μm to 3 mm, and more preferably 450 μm to 600 μm. By shortening the overall length L of the electro-conductive contact pin 100 in this way, it is possible to effectively cope with high-frequency characteristics. Also, the elastic recovery time of the elastic portion 130 can be shortened, thereby shortening the test time.

The overall thickness H and the overall width W of the electro-conductive contact pin 100 have a ratio in the range of 1:1 to 1:5. Preferably, the overall thickness H of the electro-conductive contact pin 100 is in the range of 40 μm to 200 mm, and the overall width W of the electro-conductive contact pin 100 is in the range of 40 μm to 200 μm. By shortening the overall width W of the electro-conductive contact pin 100 in this way, it is possible to implement a narrower pitch.

Meanwhile, the overall thickness H and the overall width W of the electro-conductive contact pin 100 may be configured to be substantially the same. Thus, it is not necessary to join a plurality of separately manufactured electro-conductive contact pins 100 in the thickness direction so that the overall thickness H and the overall width W become substantially the same. In addition, as it becomes possible to make the overall thickness H and the overall width W of the electro-conductive contact pin 100 substantially the same, the resistance to moments acting in the front and rear directions of the electro-conductive contact pin 100 is increased, resulting in improved contact stability. Furthermore, with the configuration in which the overall thickness H of the electro-conductive contact pin 100 is equal to or larger than 70 μm and the ratio of the overall thickness H to the overall width W thereof is in the range of 1:1 to 1:5, overall durability and deformation stability of the electro-conductive contact pin 100 can be improved and thereby contact stability with the electrode pad WP can be improved. In addition, as the overall thickness H of the electro-conductive contact pin 100 is configured to be equal to or larger than 70 μm, it is possible to improve current carrying capacity.

When the electro-conductive contact pin 100 is manufactured using a photoresist mold, the overall thickness H is inevitably smaller than the overall width W. For example, in the case of the electro-conductive contact pin 100 thus manufactured, the overall thickness H may be less than 40 μm and the overall thickness H and the overall width W may have a ratio in the range of 1:2 to 1:10. Thus, the resistance to moments that deform the electro-conductive contact pin 100 in the front and rear directions by contact pressure is weak. In order to prevent problems occurring due to excessive deformation of the clastic portion 130 on front and rear surfaces of the electro-conductive contact pin 100, it should be considered to additionally form a housing on the front and rear surfaces of the electro-conductive contact pin 100. However, according to the exemplary embodiment of the present disclosure, an additional housing is not necessary.

The method of manufacturing the electro-conductive contact pin 100 of the vertical probe card according to the exemplary embodiment of the present disclosure will be described with reference to FIGS. 9a to 9f.

FIG. 9a is a plan view illustrating a mold M in which an inner space IH is formed. FIG. 9b is a sectional view taken along line A-A′ of FIG. 9a. The mold M may be made of an anodic aluminum oxide film, a photoresist, a silicon wafer, or a material similar thereto. However, a more preferred material for the mold M is an anodic aluminum oxide film. Therefore, the electro-conductive contact pin 100 according to the exemplary embodiment of the present disclosure has an effect exhibited by the use of the mold M made of the anodic aluminum oxide film as well as an effect exhibited by the structural advantages. Hereinafter, the mold M made of the anodic aluminum oxide film will be described as a preferred embodiment of the mold M.

The anodic aluminum oxide film means a film formed by anodizing a metal as a base material, and pores mean holes formed in the process of forming the anodic aluminum oxide film by anodizing the metal. For example, when the metal as the base material is aluminum (Al) or an aluminum alloy, the anodization of the base material forms the anodic aluminum oxide film consisting of anodized aluminum (Al₂O₃) on a surface of the base material. However, the metal is not limited thereto, and includes Ta, Nb, Ti, Zr, Hf, Zn, W, Sb, or an alloy thereof. The resulting anodic aluminum oxide film includes a barrier layer in which no pores are formed therein vertically, and a porous layer in which the pores are formed therein. After removing the base material on which the anodic aluminum oxide film having the barrier layer and the porous layer is formed, only the anodic aluminum oxide film consisting of anodized aluminum (Al₂O₃) remains. The anodic aluminum oxide film may have a structure in which the barrier layer formed during the anodization is removed to expose the top and bottom of the pores, or a structure in which the barrier layer formed during the anodization remains to close one of the top and bottom of the pores.

The anodic aluminum oxide film has a coefficient of thermal expansion of 2 to 3 ppm/° C. With this, the anodic aluminum oxide film is less likely to undergo thermal deformation due to temperature when exposed to a high temperature environment. Thus, even when the electro-conductive contact pin 100 is manufactured in a high-temperature environment, a precise electro-conductive contact pin 100 can be manufactured without thermal deformation.

Since the electro-conductive contact pin 100 according to the exemplary embodiment of the present disclosure is manufactured using the mold M made of the anodic aluminum oxide film instead of a photoresist mold, there is an effect of realizing shape precision and a fine shape, which were limited in realization with the photoresist mold. In addition, when the conventional photoresist mold is used, an electro-conductive contact pin with a thickness of 40 μm can be manufactured, but when the mold M made of the anodic aluminum oxide film is used, the electro-conductive contact pin 100 with a thickness in the range of 40 μm to 200 μm can be manufactured.

A seed layer SL is provided on a lower surface of the mold M. The seed layer SL may be provided on the lower surface of the mold M before the inner space IH is formed in the mold M. Meanwhile, a support substrate (not illustrated) is formed under the mold M to improve handling of the mold M. In this case, the seed layer SL may be formed on an upper surface of the support substrate, and then the mold M having the inner space IH may be coupled to the support substrate. The seed layer SL may be made of copper (Cu), and may be formed by a deposition method.

The inner space IH may be formed by wet-etching the mold M made of the anodic aluminum oxide film. To this end, a photoresist may be provided on the upper surface of the mold M and patterned, and then the anodic aluminum oxide film in a patterned and open area may react with an etching solution to form the inner space IH.

Thereafter, a primary electroplating process is performed in the inner space IH of the mold M to form the electro-conductive contact pin 100. The primary electroplating process is a multi-layer plating process. FIG. 9c is a plan view illustrating the electroplating process performed in the inner space IH. FIG. 9d is a sectional view taken along line A-A′ of FIG. 9c.

The primary electroplating process is performed to form a first plunger 110, an clastic portion 130, a support portion 140, and a first metal portion 300 of a second plunger 120. As a result of the primary electroplating process, a plurality of metal layers are stacked in the thickness direction.

The plurality of metal layers are stacked in the thickness direction of the electro-conductive contact pin 100 by growing the metal layers in the thickness direction of the mold M, so the metal layers have a uniform cross-sectional shape in the thickness direction of the electro-conductive contact pin 100. The plurality of metal layers include a first metal layer 160 and a second metal layer 180. The first metal layer 160 may be made of a metal having relatively high wear resistance compared to the second metal layer 180, preferably a metal selected from rhodium (Rd), platinum (Pt), iridium (Ir), palladium (Pd), nickel (Ni), manganese (Mn), tungsten (W), phosphorus (Ph), or an alloy thereof, or a palladium-cobalt (PdCo) alloy or a palladium-nickel (PdNi) alloy, or a nickel-phosphorus (NiPh) alloy, a nickel-manganese (NiMn) alloy, a nickel-cobalt (NiCo) alloy, or a nickel-tungsten (NiW) alloy. The second metal layer 180 may be made of a metal having relatively high electrical conductivity compared to the first metal layer 160, preferably a metal selected from copper (Cu), silver (Ag), gold (Au), or an alloy thereof.

The first metal layer 160 is disposed on each of the upper and lower sides in the thickness direction of the electro-conductive contact pin 100, and the second metal layer 180 is disposed between the first metal layers 160. For example, the electro-conductive contact pin 100 is provided by sequentially stacking the first metal layer 160, the second metal layer 180, and the first metal layer 160, and the number of stacked layers is at least three.

After the multi-layer plating process is completed, an inner space IH for forming a second metal portion 400 is formed in the mold M. The inner space IH may be formed by wet-etching the mold M made of the anodic aluminum oxide film.

Thereafter, a secondary electroplating process is performed in the inner space IH of the mold M to form the electro-conductive contact pin 100. The secondary electroplating process is a single-layer plating process. FIG. 9e is a plan view illustrating the electroplating process performed in the inner space IH. FIG. 9f is a sectional view taken along line A-A′ of FIG. 9c.

The secondary electroplating process is performed to form the second metal portion 400. As a result of the secondary electroplating process, a single metal layer is formed to constitute the second metal portion 400. Unlike the first plunger 110, the clastic portion 130, the support portion 140, and the first metal portion 300, the second metal portion 400 is provided by a single metal layer.

According to the configuration in which an exposed lower end surface of the second metal portion 400 serves as a second contact point, the exposed lower end surface of the second metal portion 400 continuously makes contact with an object and thus is required to have high wear resistance. In this case, the second metal portion 400 may be made of a metal having relatively high wear resistance compared to the first metal layer 160, preferably a metal selected from rhodium (Rd), platinum (Pt), iridium (Ir), palladium (Pd), nickel (Ni), manganese (Mn), tungsten (W), phosphorus (Ph), or an alloy thereof, or a palladium-cobalt (PdCo) alloy or a palladium-nickel (PdNi) alloy, or a nickel-phosphorus (NiPh) alloy, a nickel-manganese (NiMn) alloy, a nickel-cobalt (NiCo) alloy, or a nickel-tungsten (NiW) alloy.

On the other hand, in some cases, according to the configuration in which the exposed lower end surface of the second metal portion 400 serves as the second contact point, the exposed lower end surface of the second metal portion 400 makes contact with the object and thus is required to have high electrical conductivity. In this case, the second metal portion 400 may be made of a metal having relatively high electrical conductivity compared to the second metal layer 160, preferably a metal selected from copper (Cu), silver (Ag), gold (Au), or an alloy thereof.

The single metal layer constituting the second metal portion 400 may be made of a material different from that of the metal layers constituting the first metal portion 300. For example, when the first metal portion 300 is constituted by alternately stacking the first metal layer 160 made of palladium-cobalt (PdCo) and the second metal layer 180 made of copper (Cu), the second metal portion 400 may be made of a single metal of rhodium (Rd). On the other hand, the single metal layer constituting the second metal portion 400 may be made of the same material as any one of the metal layers constituting the first metal portion 300. For example, when the first metal portion 300 is constituted by alternately stacking the first metal layer 160 made of palladium-cobalt (PdCo) and the second metal layer 180 made of copper (Cu), the second metal portion 400 may be made of a single metal of palladium-cobalt (PdCo) or copper (Cu).

When the electroplating process is completed, the mold M and the seed layer SL are removed. When the mold M is made of the anodic aluminum oxide film, the mold M is removed using a solution that selectively reacts with the anodic aluminum oxide film. In addition, when the seed layer SL is made of copper (Cu), the seed layer SL is removed using a solution that selectively reacts with copper (Cu).

After the plating process is completed, the temperature is raised to a high temperature and pressure is applied to pressurize the metal layers on which the plating process is completed so that the first metal portion 300 and the second metal portion 400 are made more dense. When a photoresist is used as a mold, the process of raising the temperature to a high temperature and applying pressure cannot be performed because the photoresist exists around the metal layers after the plating process is completed. On the contrary, according to the exemplary embodiment of the present disclosure, since the mold M made of the anodic aluminum oxide film is provided around the metal layers on which the plating process is completed, even when the temperature is raised to a high temperature, it is possible to densify the first metal layer 160 and the second metal layer 180 with minimized deformation because of the low coefficient of thermal expansion of the anodic aluminum oxide film. Thus, it is possible to obtain the first metal portion 300 and the second metal portion 400 with a higher density compared to the technique using the photoresist as the mold.

FIG. 10 is an actual image of the electro-conductive contact pin 100 manufactured by the method described above. FIG. 10 illustrates a state in which the mold M made of the anodic aluminum oxide film is removed.

According to the technique for manufacturing a pin by electroplating using a photoresist as a mold, it is difficult to sufficiently increase the height of the mold only with the use of a single-layer photoresist. As a result, it is also difficult to sufficiently increase the thickness of the electro-conductive contact pin. The electro-conductive contact pin needs to be manufactured with a predetermined thickness in consideration of electrical conductivity, restoring force, brittle fracture, etc. In order to increase the thickness of the electro-conductive contact pin, a mold in which photoresists are stacked in multiple layers may be used. However, in this case, each photoresist layer is slightly stepped, so that a problem occurs in that a side surface of the electro-conductive contact pin is not formed vertically and a stepped area minutely remains. In addition, when the photoresists are stacked in multiple layers, it is difficult to accurately reproduce the shape of the electro-conductive contact pin having a dimension range of equal to or less than several to several tens of μm. In particular, in the case of the photoresist mold, a photoresist is provided between inner spaces thereof. When the width of the photoresist provided between the inner spaces is equal to or less than 15 μm, the photoresist is not formed properly. In particular, when the height thereof is large compared to the width thereof, a problem occurs in that a standing state of the photoresist at the corresponding position is not properly maintained.

Therefore, when the photoresist is used as the mold, it may be difficult to make the ratio of the actual width t to the overall thickness H of the plates constituting the electro-conductive contact pin 100 in the range of 1:5 to 1:30.

However, in manufacturing the electro-conductive contact pin 100 of the vertical probe card according to the exemplary embodiment of the present disclosure by using the mold M made of the anodic aluminum oxide film, there is an advantage in that it is easy to make the actual width t and the overall thickness H of the plates constituting the electro-conductive contact pin 100 in the range of 1:5 to 1:30. Since the anodic aluminum oxide film is provided between inner spaces IH of the mold M made of the anodic aluminum oxide film, the anodic aluminum oxide film can maintain a standing state even when the distance between the inner spaces IH is in the range of 5 μm to 15 μm. As such, the use of the mold M made of the anodic aluminum oxide film makes it possible to make the overall thickness H of the electro-conductive contact pin 100 in the range of 70 μm to 200 μm, and to make the actual width t of the plates small in the range of 5 μm to 15 μm. With this, it is possible to provide the electro-conductive contact pin 100 capable of coping with high-frequency characteristics.

Referring to FIG. 11, the electro-conductive contact pin 100 of the vertical probe card according to the exemplary embodiment of the present disclosure includes a fine trench 88 provided in the side surface thereof. A plurality of fine trenches 88 are formed in the side surface of the electro-conductive contact pin 100 in a corrugated shape in which peaks and valleys with a depth in the range of 20 nm to 1 μm are repeated along the side surface of the electro-conductive contact pin 100 in a direction orthogonal to the thickness direction of the electro-conductive contact pin 100.

In the side surface of the electro-conductive contact pin 100, the fine trenches 88 are formed to extend in the thickness direction of the electro-conductive contact pin 100. In other words, the extending direction of the peaks and valleys of the fine trenches 88 corresponds to the thickness direction of the electro-conductive contact pin 100. Here, the thickness direction of the electro-conductive contact pin 100 means a direction in which a metal filling material grows during electroplating.

In a side surface of the plates constituting the electro-conductive contact pin 100, the fine trenches 88 are formed in a corrugated shape in which peaks and valleys are repeated in a direction orthogonal to the thickness direction of the plates.

The fine trenches 88 have a depth in the range of 20 nm to 1 μm and a width in the range of 20 nm to 1 μm. Here, because the fine trenches 88 are resulted from the formation of the pores formed during the manufacture of the mold M made of the anodic aluminum oxide film, the width and depth of the fine trenches 88 are less than the diameter of the pores formed in the mold M. On the other hand, in the process of forming the inner space IH in the mold M, portions of the pores of the mold M may be crushed by an etching solution to at least partially form a fine trench 88 having a depth greater than the diameter of the pores formed during the anodization.

Since the mold M made of the anodic aluminum oxide film includes a large number of pores, and at least a portion of the mold M is etched to form the inner space IH, and the metal filling material is formed in the inner space IH, the fine trenches 88 are provided in the side surface of the electro-conductive contact pin 100 as a result of contact between the electro-conductive contact pin 100 and the pores of the mold M.

Since the fine trenches 88 have a corrugated shape in which peaks and valleys with a depth in the range of 20 nm to 1 μm are repeated in a direction orthogonal to the thickness direction, they have an effect of increasing the surface area of the side surface of the electro-conductive contact pin 100. With the configuration of the fine trenches 88 formed in the side surface of the electro-conductive contact pin 100, the surface area through which a current flows can be increased by a skin effect, so that the density of the current flowing along the electro-conductive contact pin 100 can be increased, thereby improving electrical characteristics of the electro-conductive contact pin 100. In addition, with the configuration of the fine trenches 88, heat generated in the electro-conductive contact pin 100 can be rapidly dissipated, thereby suppressing a rise in the temperature of the electro-conductive contact pin 100.

FIGS. 12 and 13 are views illustrating a comparison between the vertical probe card according to the exemplary embodiment of the present disclosure and the vertical probe card according to the related art. FIG. 12 is a view illustrating a state before overdrive. FIG. 13 is a view illustrating a state after overdrive.

The left side of FIGS. 12 and 13 illustrates the vertical probe card according to the related art in which a straight pin or a cobra pin 7 is adopted, and the right side of FIGS. 12 and 13 illustrates the vertical probe card according to the exemplary embodiment of the present disclosure.

Referring to FIG. 12, the lateral width and the thickness of the electro-conductive contact pin 100 of the vertical probe card according to the exemplary embodiment of the present disclosure are equal to those of the straight pin or the cobra pin 7 of the vertical probe card according to the related art. Thus, the vertical probe card according to the exemplary embodiment of the present disclosure can be implemented as a vertical probe card capable of coping with a narrower pitch.

Referring to FIG. 13, the behavioral characteristics of the electro-conductive contact pin 7 of the vertical probe card according to the related art are different from those of the electro-conductive contact pin 100 of the vertical probe card according to the exemplary embodiment of the present disclosure. The electro-conductive contact pin 7 of the vertical probe card according to the related art has a structure in which a body thereof is elastically bent or curved in a convex shape in the horizontal direction by pressure applied to opposite ends thereof to thereby buffer the pressure. On the contrary, the electro-conductive contact pin 100 of the vertical probe card according to the exemplary embodiment of the present disclosure has a structure in which the electro-conductive contact pin 100 maintains a substantial vertical state even when pressure is applied to opposite ends thereof and the elastic portion 130 of the electro-conductive contact pin 100 is compressed along the length direction of the electro-conductive contact pin 100 to thereby buffer the pressure.

Due to the different behavioral characteristics, in the case of the vertical probe card according to the related art, when the overall length of the electro-conductive contact pin 7 is shortened, a problem occurs in that a semiconductor chip is damaged by an excessive pressing force. Thus, it is difficult to shorten the overall length of the electro-conductive contact pin 7, which is disadvantageous in testing high-frequency characteristics of the semiconductor chip. On the contrary, according to the exemplary embodiment of the present disclosure, even when the overall length of the electro-conductive contact pin 100 is shortened, it is possible to prevent an excessive pressing force from being generated on the semiconductor chip by adjusting the actual width t and the thickness of the plates constituting the clastic portion 130. Therefore, the vertical probe card according to the exemplary embodiment of the present disclosure is advantageous in testing high-frequency characteristics of the semiconductor chip.

In addition, in the case of the vertical probe card according to the related art, since the electro-conductive contact pin 7 is curved in the horizontal direction, a short-circuit problem occurs when a plurality of electro-conductive contact pins 7 are arranged at a narrower pitch. Therefore, there is a limit in arranging the electro-conductive contact pins 7 at a narrower pitch. On the contrary, according to the present disclosure, since the elastic portion 130 provided inside the support portion 140 is compressed in the length direction of the electro-conductive contact pin 100 while the support pin 140 maintains a vertical state, a short-circuit problem does not occur even when the electro-conductive contact pins 100 are arranged at a narrower pitch. Therefore, it is possible to test semiconductor chips with a narrower pitch compared to the vertical probe card according to the related art.

Next, a second embodiment according to the present disclosure will be described. However, the embodiments described below will be mainly described in terms of characteristic elements in comparison with the first embodiment, and descriptions of the same or similar elements to the first embodiment will be omitted.

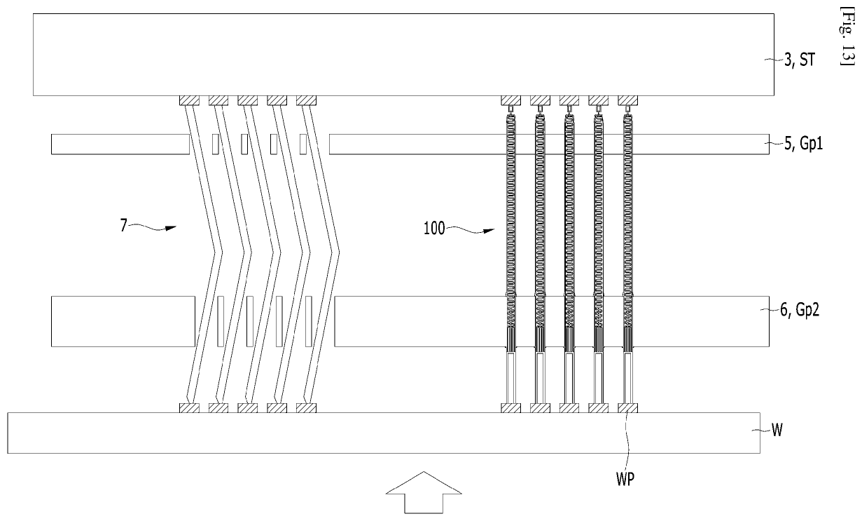

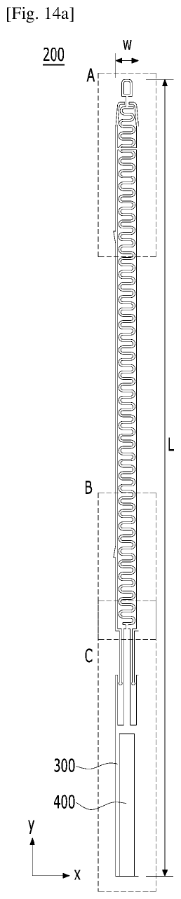

Hereinafter, an electro-conductive contact pin 200 according to a second exemplary embodiment of the present disclosure will be described with reference to FIGS. 14a to 17b.

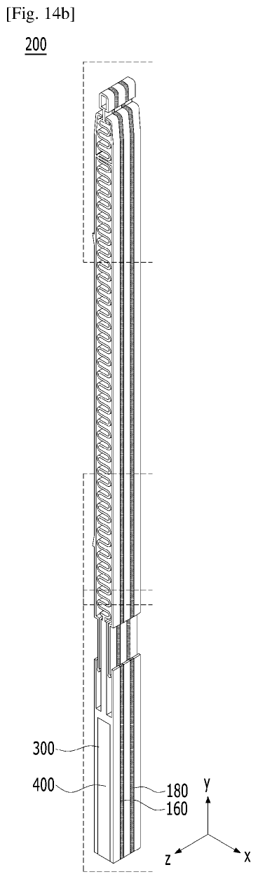

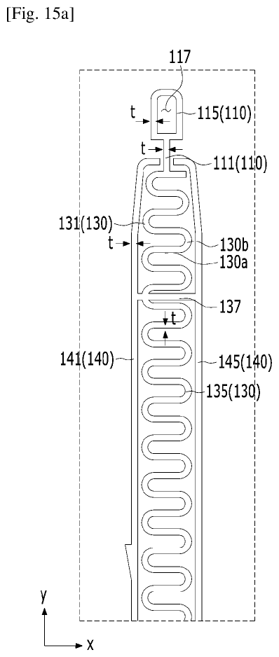

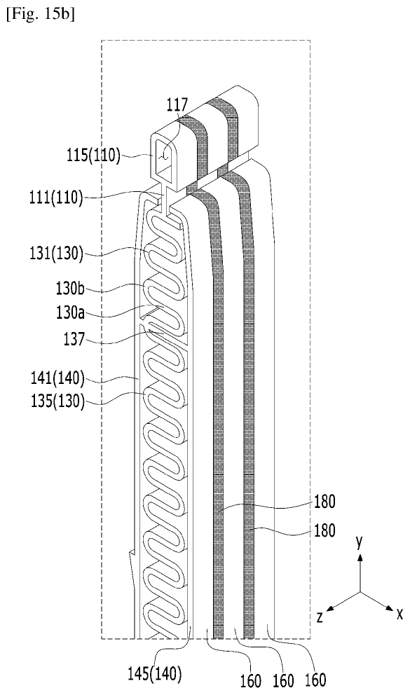

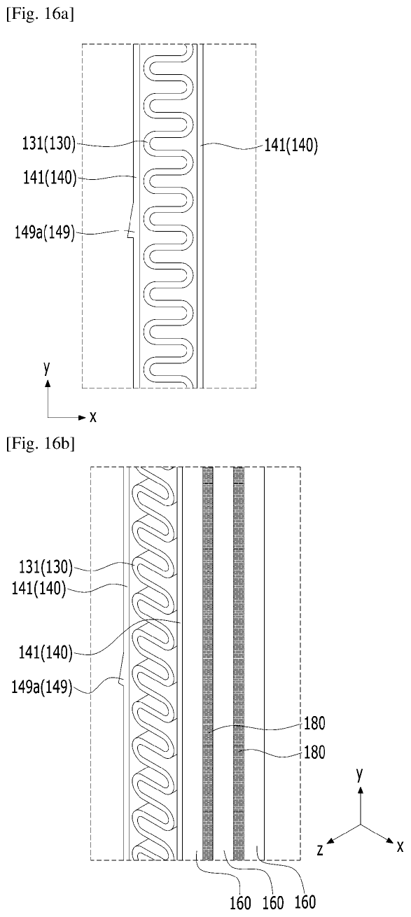

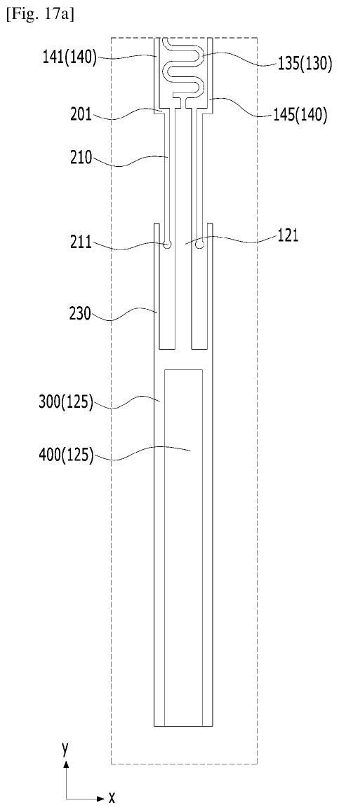

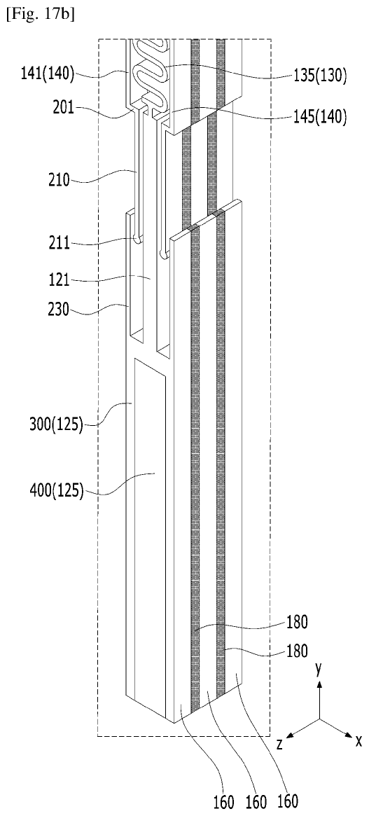

FIG. 14a is a plan view illustrating the electro-conductive contact pin according to the second exemplary embodiment of the present disclosure. FIG. 14b is a perspective view illustrating the electro-conductive contact pin according to the second exemplary embodiment of the present disclosure. FIG. 15a is an enlarged plan view of part A illustrated in FIG. 14a. FIG. 15b is an enlarged perspective view of part A illustrated in FIG. 14a. FIG. 16a is an enlarged plan view of part B illustrated in FIG. 14a. FIG. 16b is an enlarged perspective view of part B illustrated in FIG. 14a. FIG. 17a is an enlarged plan view of part C illustrated in FIG. 14a. FIG. 17b is an enlarged perspective view of part C illustrated in FIG. 14a.

The electro-conductive contact pin 200 according to the second exemplary embodiment of the present disclosure remains the same as that according to the first exemplary embodiment, except for the structure for limiting an upward stroke of a protruding tip 125.

The protruding tip 125 of the electro-conductive contact pin 200 includes a protruding guide wall 230 extending and protruding in the length direction from an upper surface thereof. A support portion 140 of the electro-conductive contact pin 200 includes a stopper 210 extending and protruding in the length direction from a lower end thereof.

The stopper 210 includes a stepped portion 201 stepped toward a second neck portion 121. The lateral width of the stopper 210 is configured to be smaller than that of the support portion 140.

The stopper 210 is positioned between the second neck portion 121 and the guide wall 230. An enlarged portion 211 is formed at an end of the stopper 210. The enlarged portion 211 is formed in a spherical shape with a circular cross-section.

The length of the stopper 210 is configured to be longer than that of the guide wall 230. When the protruding tip 125 is vertically moved upward, an upper surface of the protruding tip 125 and the end of the stopper 210 are brought into contact with each other. More specifically, as the upper surface of the protruding tip 125 between the guide wall 230 and the second neck portion 121 is brought into contact with the enlarged portion 211 of the stopper 210, the protruding tip 125 is limited from being further moved upward. With this, it is possible to prevent a second clastic portion 135 from being excessively compressed.

Of course, alternatively, the length of the guide wall 230 may be configured to be longer than that of the stopper 210. In this case, the guide wall 230 is brought into contact with the stepped portion 201 to limit the protruding tip 125 from being further moved upward.

When the protruding tip 125 is tilted by an eccentric force, the second neck portion 121 is brought into surface contact with the stopper 210. When the protruding tip 125 is further tilted by the eccentric force, the guide wall 230 and the stopper 210 are brought into surface contact with each other. With this, an additional current path can be formed even during the tilting of the protruding tip 125, thereby enabling a stable electrical connection.

In the foregoing, the vertical probe card has been described an example of a test device, but test devices that can use the electro-conductive contact pin according to the exemplary embodiments of the present disclosure are not limited thereto and include any test device for checking whether a test object is defective by applying electricity.

In addition, the present disclosure is also applicable to a socket pin while including the technical features according to the exemplary embodiment of the present disclosure described above. In applying the configuration described with the example of a probe pin to the socket pin, the dimensions and/or the shape of a contact point may be modified so that a semiconductor package can be tested, but the same technical effect can be obtained by applying the technical features according to the exemplary embodiment of the present disclosure to the socket pin.

As described above, the present disclosure has been described with reference to the exemplary embodiments. However, those skilled in the art will appreciate that various modifications, additions, and substitutions are possible, without departing from the scope and spirit of the disclosure as disclosed in the accompanying claims.

### DESCRIPTION OF THE REFERENCE NUMERALS IN THE DRAWINGS

100: electro-conductive contact pin
110: first plunger
120: second plunger
130: elastic portion
140: support portion

1. An electro-conductive contact pin comprising:
a first plunger positioned at a first end side of the electro-conductive contact pin and having an end serving as a first contact point;
a second plunger positioned at a second side of the electro-conductive contact pin and having an end serving as a second contact point; and
an elastic portion having a repetitive bending pattern and configured to elastically displace the first plunger and the second plunger in a length direction of the electro-conductive contact pin,
wherein the second plunger comprises a first metal portion and a second metal portion, and the second metal portion is in contact with a side surface of the first metal portion.

2. The electro-conductive contact pin of claim 1, wherein the first metal portion is provided by stacking a plurality of metal layers, and
the second metal portion is provided by a single metal layer.

3. The electro-conductive contact pin of claim 1, wherein the first metal portion is provided by stacking at least three metal layers, and
the second metal portion is in contact with the first metal portion at least one interface.

4. The electro-conductive contact pin of claim 1, wherein the first metal portion surrounds three side surfaces of the second metal portion, and a side surface of the second metal portion not surrounded by the first metal portion serves as the second contact point.

5. The electro-conductive contact pin of claim 1, wherein the first metal portion, the second metal portion, and the first metal portion are positioned sequentially in a widthwise cross-section of the second plunger.

6. The electro-conductive contact pin of claim 1, wherein the second metal portion is composed of a single metal layer, and the single metal layer constituting the second metal portion is made of a material different from that of a metal layer constituting the first metal portion.

7. The electro-conductive contact pin of claim 1, wherein the first plunger and the elastic portion are provided by stacking a plurality of metal layers the same as a metal layer constituting the first metal portion, and the second metal portion is provided by a single metal layer.

8. The electro-conductive contact pin of claim 1, wherein a support portion configured to guide the elastic portion to be compressed and extended in the length direction of the electro-conductive contact pin and configured to prevent the elastic portion from being buckled when compressed is provided outside the elastic portion along the length direction of the electro-conductive contact pin.

9. The electro-conductive contact pin of claim 8, wherein an actual width of a plate constituting the support portion is equal to an actual width of a plate constituting the elastic portion.

10. The electro-conductive contact pin of claim 8, wherein the first plunger, the second plunger, the elastic portion, and the support portion are integrally connected to each other to form a single body.

11. The electro-conductive contact pin of claim 1, wherein the elastic portion has a uniform cross-sectional shape in a thickness direction of the electro-conductive contact pin, and
the elastic portion has a uniform thickness throughout.

12. The electro-conductive contact pin of claim 1, wherein a fine trench is provided in a side surface of each of the first plunger, the second plunger, and the elastic portion.

13. The electro-conductive contact pin of claim 1, wherein the elastic portion comprises:
a first elastic portion connected to the first plunger;
a second elastic portion connected to the second plunger; and
an intermediate fixing portion connected to the first elastic portion and the second elastic portion between the first elastic portion and the second elastic portion and provided integrally with the support portion.

14. A vertical probe card that is used in a test process of testing a chip manufactured on a wafer during a semiconductor manufacturing process and is capable of coping with a narrower pitch, the vertical probe card comprising:
a space transformer having a connection pad;
a guide plate provided under the space transformer so as to be spaced apart from the space transformer; and
an electro-conductive contact pin inserted and installed into a hole of the guide plate,
wherein the electro-conductive contact pin comprises:
a first plunger positioned at a first end side of the electro-conductive contact pin and having an end serving as a first contact point;
a second plunger positioned at a second side of the electro-conductive contact pin and having an end serving as a second contact point; and
an elastic portion having a repetitive bending pattern and configured to elastically displace the first plunger and the second plunger in a length direction of the electro-conductive contact pin,
wherein the second plunger comprises a first metal portion and a second metal portion, and the second metal portion is in contact with a side surface of the first metal portion.

15. The vertical probe card of claim 14, wherein a support portion configured to guide the elastic portion to be compressed and extended in the length direction of the electro-conductive contact pin and configured to prevent the elastic portion from being buckled when compressed is provided outside the elastic portion along the length direction of the electro-conductive contact pin, and
a locking portion configured to allow the support portion to be caught and fixed to the guide plate is provided on an outer wall of the support portion.
